(19) United States
(12) Patent Application Publication
(10) Pub. No.: US 2024/0147640 A1
(43) Pub. Date: May 2, 2024

(54) COVER PLATE AND BOX BODY FOR SERVER

(71) Applicant: Fulian Precision Electronics (Tianjin) Co., Ltd., Tianjin (CN)

(72) Inventors: Chang-You ZHANG, Tianjin (CN); Zhi-Hua HAN, Tianjin (CN); Rui-Fang LV, Tianjin (CN)

(21) Appl. No.: 18/406,401

(22) Filed: Jan. 8, 2024

Related U.S. Application Data
(62) Division of application No. 17/587,118, filed on Jan. 28, 2022.

(30) Foreign Application Priority Data
Apr. 13, 2021 (CN) 202110396931.8

(51) Int. Cl. H05K 5/02; B21D 26/021; B23P 15/00; H05K 7/14

(52) U.S. Cl. CPC H05K 5/0208; B21D 26/021; B23P 15/00; H05K 5/0217; H05K 7/1487

(57) ABSTRACT

A cover plate of a box body for a server includes a main body, a folding edge, and a buckle. The folding edge is vertically connected to the main body, the buckle is disposed on the folding edge, and the buckle can extend along one side of the folding edge and face the main body.

### FIELD

The present disclosure relates to the technical field of server bodies, in particular to a cover plate and a box body.

### BACKGROUND

At present, the fastening structure of server cover plate and base can adopt “i-nail” structure or “overpass” structure. However, the “i-nail” structure requires hardware to be rivetted on the side of the cover plate, which increases the cost of hardware, resulting in low production capacity and low yield because of high rates of defects in production. The “overpass” structure may cause holes on the flat edge of the cover plate. The “overpass” needs elongation and is deformed after being formed because the “overpass” needs to pass through many die stations, and there is a high risk of fracturing in the elongated deformation when the “overpass” is used for fastening. Resulting weak fastening structures.

Therefore, improvement is desired.

### BRIEF DESCRIPTION OF THE DRAWINGS

FIG. 1 is a schematic diagram of an overpass structure of a server body according to an embodiment of the present disclosure.

FIG. 2 is a schematic diagram of a cover plate of the overpass structure according to an embodiment of the present disclosure.

FIG. 3 is a schematic diagram of a box body for a server of an embodiment of the present disclosure.

FIG. 4 is a flowchart of a manufacturing method of a box body according to an embodiment of the present disclosure.

### DETAILED DESCRIPTION

The technical solutions in the embodiments of the present disclosure will be described in conjunction with the accompanying drawings in the embodiments of the present disclosure. Obviously, the described embodiments are part of the embodiments of the present disclosure, not all of them. Based on the embodiments of the present disclosure, all other embodiments obtained by those of ordinary skill in the art without creative work shall fall within the protection scope of the present disclosure.

The following disclosure provides many different embodiments or examples to implement different structures. In order to simplify the disclosure, the components and settings of specific examples are described below. Of course, they are merely examples and are not intended to limit the present application. In addition, the present application may repeat reference numbers and reference letters in different examples for the purpose of simplification and clarity, which itself does not indicate a relationship between the various embodiments and settings discussed.

The embodiments of the present disclosure provide a cover plate, the cover plate includes a main body, a folding edge, and a buckle. The folding edge is vertically connected to the main body, the buckle is disposed on the folding edge, and the buckle can extend along one side of the folding edge to face the main body.

A number of buckles on the folding edge are vertically connected to the main body, the buckles extend along one side of the folding edge and face the main body, and such operation using buckles does not increase the cost by using additional hardware. In addition, the snap-type attachment provided by the present disclosure has a large snap contact surface, which can enhance the tensile resistance and snap strength, and there is no gap in the appearance of the box body after attaching by snapping, improving aesthetics.

Some embodiments of the present disclosure are described in detail below in combination with the accompanying drawings.

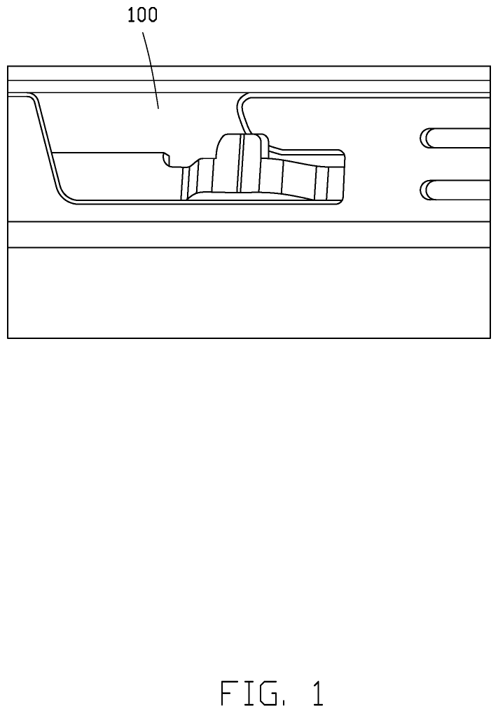

FIG. 1 illustrates an overpass structure in accordance with an embodiment of the present disclosure. When the overpass structure uses buckles, it is necessary to push the folded edge of a cover plate 100 to make the overpass, the molded steps occupy more space, and the strength of the overpass structure is diminished, dimensional stability is poor.

In the tensile test for the overpass structure with the buckle structure, the test results are shown in Table 1 below:

TABLE 1
Tensile test results of overpass structure

| Sample | Tensile/KG | Sample Status |
|---|---|---|
| 1 | 16.01 | distortion free |
| 2 | 15.98 | distortion free |
| 3 | 15.89 | distortion free |
| 4 | 15.97 | distortion free |
| 5 | 15.87 | distortion free |

It can be seen from the above test results that the buckle of the overpass structure is not deformed when the tensile resistance range is 15.87 kg-16.01 kg, and the tensile strength is high.

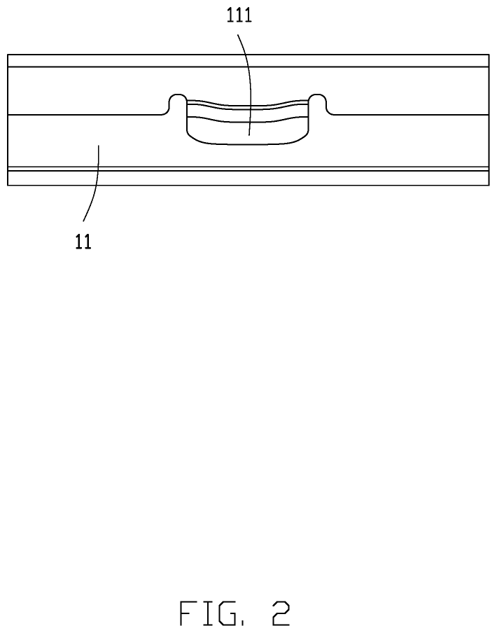

The present disclosure also provides a cover plate 100 (shown in FIG. 2).

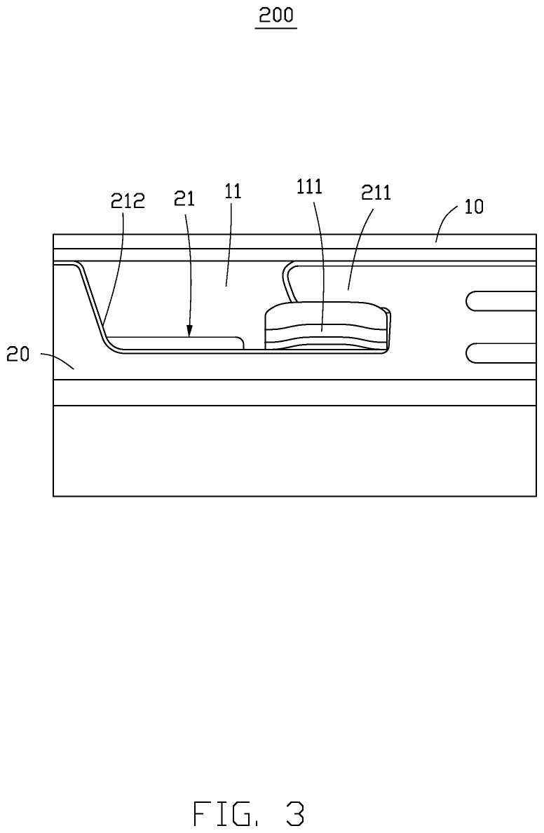

FIGS. 2 and 3 illustrate a cover plate 100 in accordance with an embodiment of the present disclosure.

The cover plate 100 includes a main body 10, a folding edge 11, and a plurality of buckles 111. The main body 10 is vertically connected to the folding edge 11, and the buckles 111 are disposed on the folding edge 11. The buckles 111 extend from one side of the folding edge 11 and face the main body 10. In the present disclosure, the buckles 111 are disposed on the folding edge 11 and vertically connected to the main body 10, the buckles 111 extend along one side of the folding edge 11 and face the main body 10. The buckling operation is completed through the buckle 111 alone, without cost of additional hardware. The buckle 111 provided by the present disclosure has a large snap contact surface, which enhances tensile resistance and strength and strength of the snapped attachment, and there is no gap in the appearance of the box body 200 after snapping.

In one embodiment, the buckle 111 includes an L-shape or an arc shape. It can be understood that the shape of the buckle 111 is not limited to the above limitations, and can also be other shape, such as Z-type.

In one embodiment, in the tensile test of the buckle 111 provided in the present disclosure, the test results are shown in Table 2 below:

TABLE 2
Tensile test results of the buckle of the present disclosure

| Sample | Tensile/KG | Sample Status |
|---|---|---|
| 1 | 39.7 | distortion free |
| 2 | 39.64 | distortion free |
| 3 | 39.68 | distortion free |
| 4 | 39.72 | distortion free |
| 5 | 39.69 | distortion free |

It can be seen from the above test results that the tensile resistance of the buckle 111 being in the 39.64 kg-39.72 kg range causes no deformation at all, a high tensile strength exists.

Referring to FIG. 3, the present disclosure also provides a box body 200. The box body 200 includes a base 20 and the cover plate 100. The base includes a groove 21, and the groove 21 is matched with the buckle 111. The groove 21 is provided with a limiting member 211 for limiting the position of the buckle 111 when the buckle 111 extends into the groove 21 and slides in the groove 21.

In one embodiment, an Inclined plane 212 is arranged on the side opposite to the limiting member 211 on the groove 21, and the inclined angle of the Inclined plane 212 is 110 degrees. It can be understood that the inclination angle of the Inclined plane 212 is not limited to the above limitations, but can also be other angles, such as 105 degrees, 106 degrees, 107 degrees, 108 degrees, 109 degrees, 115 degrees, or 1base 20 degrees.

In one embodiment, the length of the limiting member 211 is greater than the length of the buckle 111. For example, the length of the groove 21 may be 34.64 mm, the length of the buckle 111 may be 11 mm, and the length of the limiting member 211 may be 14.10 mm, not limited herein. In other embodiments, as shown in FIG. 3, the length of the limiting member 211 is greater than three-quarters of the length of the buckle 111.

In one embodiment, the limiting member 211 may be retractable structure, for example, the limiting member 211 may be in the form of a pipe sleeve, the limiting member 211 may include a first pipe sleeve (not shown) and a second pipe sleeve (not shown). The first pipe sleeve is arranged on the second pipe sleeve, and the first pipe sleeve can slide on the second pipe sleeve to extend or shorten the length of the limiting member 211. By extending and retracting the limiting member 211, the limiting member 211 can apply to buckles 111 of different lengths and specifications, and the fastening is improved.

In one embodiment, one side of the base 20 connected to the Inclined plane 212 can be provided with a groove (not shown in the figure), the groove is provided with an elastic element (not shown in the figure) and a pin (not shown in the figure) butted with the elastic element. One end of the pin is located above the groove, the pin can be an arc pin, the elastic element can be a spring, which is not limited here. The groove can be arranged on the base 20 at a position consistent with the length of the limiting member 211, which is used to fix the buckle 111 through the bolt after the buckle 111 extends into the groove 21 and reaches the position limited by the limiting member 211, so as to increase the stability of the buckle 111 when buckled and the groove 21.

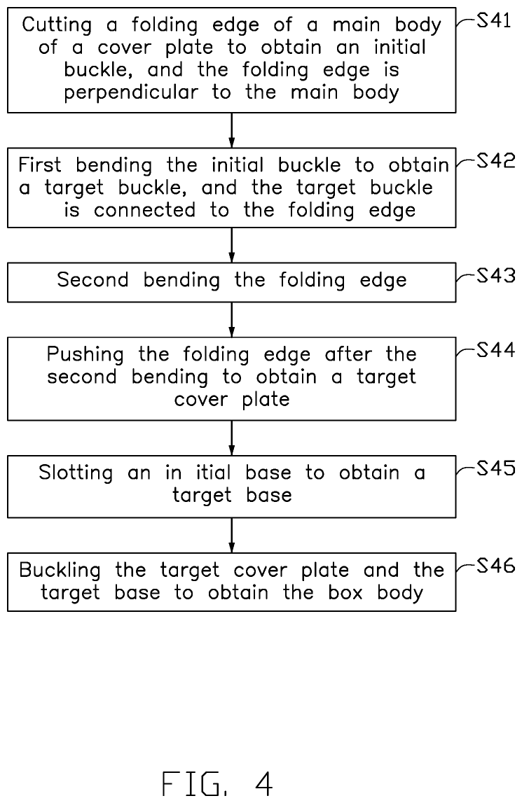

FIG. 4 is a flowchart depicting an embodiment of a box body manufacturing method.

Each block shown in FIG. 4 represents one or more processes, methods, or subroutines, carried out in the example method. Furthermore, the illustrated order of blocks is illustrative only and the order of the blocks can change. Additional blocks can be added or fewer blocks may be utilized, without departing from the present disclosure. The example method can begin at block 41.

At block 41, cutting a folding edge of a main body of a cover plate to obtain an initial buckle, the folding edge being perpendicular to the main body.

At block 42, a first bending is applied to the initial buckle to obtain a target buckle, and the target buckle is connected to the folding edge.

At block 43, a second bending is applied to the folding edge.

At block 44, pushing the folding edge after the second bending to obtain a target cover plate.

At block 45, creating a slot in an initial base to obtain a target base.

At block 46, buckling the target cover plate and the target base to obtain the box body.

In one embodiment, the first bending includes a Z-shaped bending, and the second bending includes a vertical bending treatment.

In one embodiment, the slotting treatment applied to an initial base to obtain a target base includes:

Disposing a groove 21 at a preset position of the initial base; and disposing a limiting member 211 on one side of the groove 21. The limiting member 211 is used to limit the position of the buckle 111 when the buckle 111 extends into the groove 21 and slides in the groove 21.

The cover plate 100, the box body 200, and the box body manufacturing method of the present disclosure are provided with a plurality of the buckles 111 on the folding edge 11 vertically connected to the main body 10. The buckle 111 extends from one side of the folding edge 11 and faces the main body 10. The buckle 111 can perform the buckling function without adding additional hardware cost, and can reduce the product cost of the buckle structure. The buckle 111 has a large snapped contact surface, which can enhance the tensile resistance and snap strength, and the appearance of the box body 200 shows no gap after snapping.

Those of ordinary skill in the art should realize that the above embodiments are only used to illustrate the present disclosure, but not to limit the present disclosure. As long as they are within the essential spirit of the present disclosure, the above embodiments are appropriately made. Changes and changes fall within the scope of protection of the present disclosure.

What is claimed is:

1. A cover plate comprising:
a main body;
a folding edge vertically connected to the main body; and
a buckle disposed on the folding edge,
wherein the buckle extends along one side of the folding edge and faces the main body.

2. The cover plate of claim 1, wherein:
a profile of the buckle comprises at least one of an L-shape and an arc shape.

3. The cover plate of claim 2, wherein:
when a tensile force in a range from 39.64 kg to 39.72 kg is applied to the buckle, and the buckle is not deformed under the tensile force.

4. A box body comprising:
a base comprising a groove; and
a cover plate comprising a main body, a folding edge, and a buckle, wherein the folding edge is vertically connected to the main body, the buckle is disposed on the folding edge, and the buckle extends along one side of the folding edge and faces the main body,
and a profile of the groove matches with a profile of the buckle.

5. The box body of claim 4, wherein:
the box body further comprises a limiting member, and the limiting member is disposed in the groove, the limiting member limits a position of the buckle when the buckle extends into the groove and slides in the groove.

6. The box body of claim 5, wherein:
the groove defines an inclined surface, and the inclined surface is arranged on a side of the groove opposite to the limiting member.

7. The box body of claim 6, wherein:
an inclination angle of the inclined surface is 110 degrees.

8. The box body of claim 1, wherein:
a length of a limiting member is greater than a length of the buckle.

9. The box body of claim 8, wherein:
the length of the limiting member is greater than three-quarters of the length of the buckle.

10. The box body of claim 1, wherein:
the limiting member is a retractable structure.

11. A box body comprising:
a limiting member;
a base comprising a groove; and
a cover plate comprising a main body, a folding edge, and a buckle, wherein the folding edge is vertically connected to the main body, the buckle is disposed on the folding edge, and the buckle extends along one side of the folding edge and faces the main body,
a profile of the groove matches with a profile of the buckle,
a length of a limiting member is greater than a length of the buckle, and the limiting member is a retractable structure.

12. The box body of claim 11, wherein:
the limiting member is disposed in the groove, the limiting member limits a position of the buckle when the buckle extends into the groove and slides in the groove.

13. The box body of claim 12, wherein:
the groove defines an inclined surface, and the inclined surface is arranged on a side of the groove opposite to the limiting member.

14. The box body of claim 13, wherein:
an inclination angle of the inclined surface is 110 degrees.

15. The box body of claim 14, wherein:
the length of the limiting member is greater than three-quarters of the length of the buckle.
